(19) United States
(12) Patent Application Publication
(10) Pub. No.: US 2024/0013033 A1
(43) Pub. Date: Jan. 11, 2024

(54) LARGE SCALE MASK OPTIMIZATION WITH CONVOLUTIONAL FOURIER NEURAL OPERATOR AND LITHO-GUIDED SELF LEARNING

(71) Applicant: NVIDIA Corp., Santa Clara, CA (US)

(72) Inventors: Haoyu Yang, Cedar Park, TX (US); Haoxing Ren, Austin, TX (US)

(73) Assignee: NVIDIA Corp., Santa Clara, CA (US)

(21) Appl. No.: 18/163,603

(22) Filed: Feb. 2, 2023

Related U.S. Application Data
(60) Provisional application No. 63/343,844, filed on May 19, 2022.

(51) Int. Cl. G06N 3/0464; G03F 1/36

(52) U.S. Cl. CPC G06N 3/0464; G03F 1/36

(57) ABSTRACT

A circuit mask optimizer utilizes a Convolutional Fourier Neural Operator (CFNO) to efficiently learn layout tile dependencies, enabling stitch-less largescale mask optimization with limited intervention of legacy tools. Litho-guided self training via a trained machine learning model provides non-convex optimization, enabling iterative model and dataset refinements at a substantial performance improvement over conventional solutions.

### CROSS REFERENCE TO RELATED APPLICATIONS

This application claims priority and benefit under 35 USC 119 to U.S. Application Ser. No. 63/343,844, “LARGE SCALE MASK OPTIMIZATION WITH CONVOLUTIONAL FOURIER NEURAL OPERATOR AND LITHO-GUIDED SELF LEARNING”, filed on May 19, 2022, the contents of which are incorporated herein by reference in their entirety.

### BACKGROUND

Mask optimization for circuit fabrication is a process to identify a mask design such that the final pattern on a silicon wafer post-lithography process is close to the target design. Conventional model-based solutions or inverse lithography techniques (ILT) perform this process using numeric or heuristic optimization that interactively queries lithography models. A limitation of these solutions is their performance. Often the constraints of circuit design and manufacturing require fast turnaround times between design and mask optimization that these conventional approaches are challenged to meet.

Attempts to apply machine learning models to mask optimization also encountered challenges. Conventional machine learning models may rely on legacy optical proximity correction (OPC) engines and that do not account for sub-optimal training sets. Some conventional machine learning model solutions focus on fixed-sized, small tile mask optimization, and do not scale well to large-scale mask design optimization problems. Some conventional machine learning models are based on convolution neural networks with limited capacity to take into account global information pertinent to mask optimization tasks.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 is a visual depiction of mask optimization.

FIG. 2 depicts a mask quality measurement 200 in one embodiment.

FIG. 3 depicts a Fourier neural operator 300 data pipeline.

FIG. 4 depicts a convolutional Fourier neural operator 400 in one embodiment.

FIG. 5 depicts a CFNO-based mask optimizer network 500 in one embodiment.

FIG. 6 depicts an embodiment of an observation refinement algorithm 600.

FIG. 7A depicts part of a circuit design comprising via arrays.

FIG. 7B depicts a mask generated by a level-set ILT algorithm.

FIG. 7C depicts a nominal resist image from an ILT-generated mask.

FIG. 7D depicts a mask generated by a machine learning model.

FIG. 7E depicts a nominal resist image generated from an ML-generated mask.

FIG. 8A depicts part of a circuit design comprising via arrays.

FIG. 8B depicts a mask generated by a level-set ILT algorithm.

FIG. 8C depicts a nominal resist image from an ILT-generated mask.

FIG. 9 depicts a parallel processing unit 902 in accordance with one embodiment.

FIG. 10 depicts a general processing cluster 1000 in accordance with one embodiment.

FIG. 11 depicts a memory partition unit 1100 in accordance with one embodiment.

FIG. 12 depicts a streaming multiprocessor 1200 in accordance with one embodiment.

FIG. 13 depicts a processing system 1300 in accordance with one embodiment.

FIG. 14 depicts an exemplary processing system 1400 in accordance with another embodiment.

FIG. 15 depicts a graphics processing pipeline 1500 in accordance with one embodiment.

### DETAILED DESCRIPTION

Embodiments of a neural network structure are disclosed (Convolutional Fourier Neural Operators, i.e., CFNOs) with improved properties for implementing large-scale mask optimization tasks. In various embodiments, a CFNO comprises a token-shared FNO unit that mitigates the limitations of Fourier Transforms on large inputs. A token-wise convolution layer of the CFNO implements effective local-global mixing in large-scale mask optimization tasks.

Herein, it should be understood that “optimized” and “optimization” and the like do not refer to theoretically ideal values/settings/configurations, but rather to values/settings/configurations that meet or exceed practical design and/or manufacturing constraints.

Mask optimization may be modeled as a non-convex optimization problem such that certain configured objectives are minimized. Solutions obtained from the model are evaluated through an evaluation algorithm, and in practice are not optimal. Thus, the machine learning generated results are not necessarily bad even they differ from the training golden value by a substantial margin. The training set and the machine learning model may alternatively be updated based on such evaluations to improve future performance.

Compared to ILT and model-based OPC, a trained CFNO model may generate an optimized mask with greater efficiency (e.g., faster), meeting or exceeding industry turn-around requirements from design to production. No iterative numerical optimization need be implemented in the model.

The FNO component of the CFNO is a circuit physics-informed structure comprising inductive bias in the network design. This contrasts with pure CNN-based structures utilized in conventional approaches. The training process for the CFNO comprises iterative refinement of the training set and the model concurrently, yielding faster convergence and improved model performance over conventional approaches.

The FNO component receives an embedding tensor input and performs a mixing function to learn global perception following Fourier Transform, frequency mixing, and inverse Fourier Transform. This processing pipeline approximates localized lithography processes, and thus enables the system to learn lithography behaviors efficiently. However, unlike local lithography optimization tasks, mask optimization tasks also utilize global circuit parameters (features and behaviors of the entire circuit, not limited to a local region). Failing to take these global parameters into account may result in additional cost to correct the mask when performing tile-based full-chip mask optimization. Therefore, mask optimization tasks utilize high-resolution and large-tile inputs to capture or approximate global circuit features. Doing so however imposes high computing cost when utilizing conventional FNO structures, due to utilization of multiple Fourier Transforms in the processing pipeline.

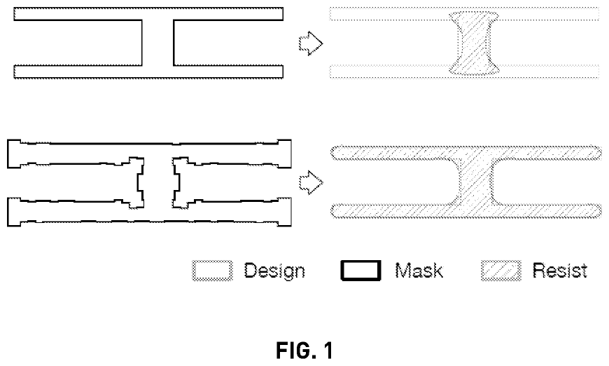

FIG. 1 is a visual depiction of a mask optimization. Mask optimization involves techniques such as Optical Proximity Correction (OPC) and Inverse Lithographic Technology (ILT). OPC is a photolithography enhancement technique commonly used to compensate for image errors due to diffraction or process effects. The need for OPC arises due to the limitations of light to maintain the edge placement integrity of the original circuit design, after processing, into the etched image on the silicon wafer. Projected images appear with irregularities such as line widths that are narrower or wider than designed, which are amenable to compensation by changing the pattern on the photomask used for imaging. Other distortions such as rounded corners are driven by the resolution of the optical imaging tool and are harder to compensate for. Such distortions, if not corrected for, may significantly alter the electrical properties of what was being fabricated. OPC corrects these errors by moving edges or adding extra polygons to the pattern written on the photomask.

OPC typically begins with a simple pattern, and iterates through variations of pitch and feature sizes, assessing the printability at each iteration and generating a model with adjustments at specific locations on the design pattern.

ILT is a method of using non-Manhattan shapes on the photomask to produce a wafer more resilient to manufacturing variation. It relies on multi-beam mask writing, which writes masks at the same speed regardless of the complexity of shape. Typical masks, including those based on optical and extreme ultraviolet lithography, comprise small features that resemble rectangles, or so-called Manhattan shapes. In some cases, photomasks have simple curve or rectilinear shapes. However at advanced process nodes (smaller devices in denser arrangements) more advanced masks may be desired.

ILT uses mathematics to calculate the desired shapes on a photomask, which are free-form curvilinear types. ILT not only increases the process windows in chip manufacturing, but it also improves the performance for a shape on the wafer. That's important for small and complex features that are difficult to print.

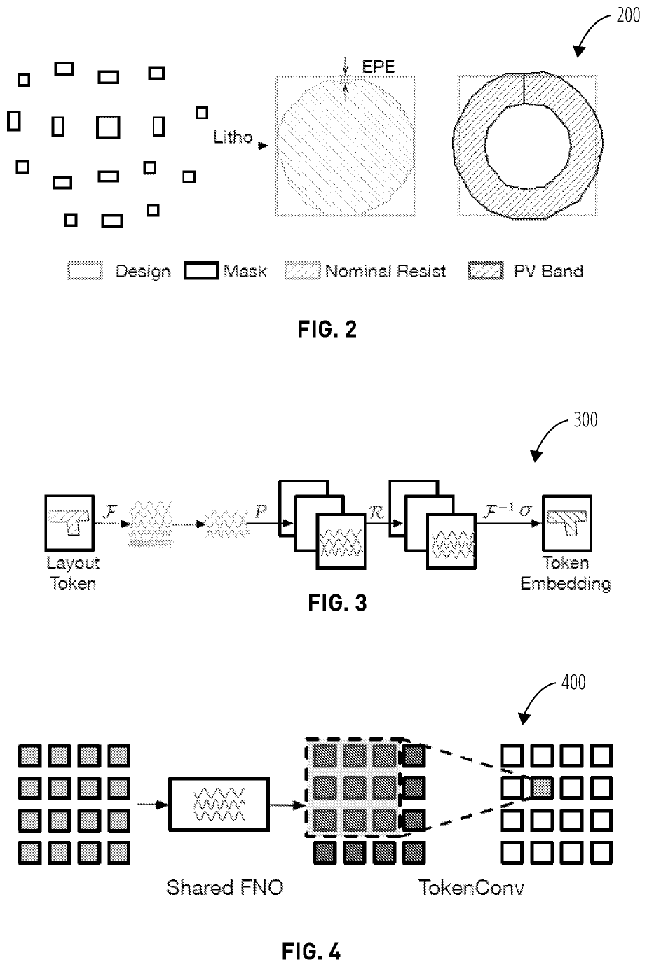

FIG. 2 depicts a mask quality measurement 200 in one embodiment. Mask optimization (MO) is a problem to find a proper mask M associated with a design Zₜ, such that the difference between the resist image Z after the forward lithography modeling and the design is minimized. There are many evaluation metrics available to estimate the quality of mask optimization solutions. Well-accepted ones are edge-placement-error (EPE) violations, mean square error (MSE) and process variation band (PVB) area. EPE and PVB are depicted in FIG. 2.

EPE is measured as the geometric distance between the target edge and the lithographic contour printed at nominal conditions. Mean square error (MSE) measures the pixel-wise difference between the design and the resist image as in: MSE=∥Z−Zt∥²_{F}. PVB area is evaluated by running lithography simulation at different corners on the final mask solution. Once run, a process variation band metric may be defined as the XOR of all the contours. The total area of the process variation band is defined as PVB Area.

Both EPE and MSE directly measure the error between resist images and designs. MSE evaluates the resist image from a more general perspective while EPE focuses on critical measurement points. PVB targets the robustness of masks subject to potential process variations.

A machine learning-based mask optimization model may be characterized as follows: Given a set of designs Ztr={Z*_{tr,1}, Z*_{tr,2}, . . . , Z*_{tr,n}} and their corresponding masks from some mask optimization engine Mₜᵣ={M_{tr,1},M_{tr,2}, . . . ,M_{tr,n}}, the machine learning model ƒ(·,W) for new designs Z*ₜₑ={Z*_{te,1}, Z*_{te,2}, . . . , Z*_{te,m}}, ƒ will generate the corresponding masks Mₜₑ=ƒ (Z_{*te})={M_{te,1},M_{te,2}, . . . ,M_{te,n}} and the mask quality measured in terms of EPE Violation, MSE and PVB Area is optimized.

A Fourier Neural Operator implements a kernel κ integral at some token g:

u=σ( [symbol] ⁻¹( [symbol] κ· [symbol] ν)), Equation 1

where F and F⁻¹ denote the Fourier Transform and the Inverse Fourier Transform, u, ν represent continuous functions, and σ is some activation function. Let ν be the input image token. Equation (1) can be rewritten into the discrete form:

U=σ( [symbol] ⁻¹( [symbol] (K)· [symbol] (V))), Equation 2

where V, K, U∈R^{h×w} represent the to,ken image, global convolution kernel and token embedding, respectively. Equation (2) is equivalent to

U=σ(K⊗V), Equation 3

which shows that an FNO may operate as a lithography learner. The global convolution kernel K may not be explicitly trained to preserve computing overhead. Instead, a frequency mixing weight W=F(K)∈C^{h×w} may be utilized and Equation (2) becomes

U=σ( [symbol] ⁻¹(W· [symbol] (V))) Equation 4.

Because the FNO is designed for global information acquisition, in practical implementations, only low frequency components are preserved for F(V). Also, F(V) may be mapped to a higher dimension through channel lifting before convolving with the global convolution kernel. To simplify and focus the relevant description, these settings are not reflected in the equations.

A Fourier neural operator 300 data pipeline is depicted in FIG. 3. In a conventional FNO, the size of V determines the receptive field of the global convolution. This poses challenges when dealing with masks, which have long-range spatial dependencies (e.g., across an entire chip or large percentile areas thereof). Mask optimization of a particular shape is affected by the characteristics of its neighbor circuits within a reasonable radius, which requires a relatively reduced dimension of V. Mask optimization may therefore be performed on large tile units of the mask to improve the efficiency of resolving boundary inconsistency (i.e., stitching issues). In conventional FNO, these constraints often require the computation of Fourier Transforms on very large inputs which is computationally inefficient.

A novel Convolutional Fourier Neural Operator addresses the limitations of conventional FNO structures and provides efficient global layout token embedding by efficiently resolving layout long-range dependencies that cause stitching issues.

The core components of a convolutional Fourier neural operator 400 (CFNO) comprise a token shared FNO and a token-wise convolution operator as depicted in the convolutional Fourier neural operator 400 of FIG. 4. The token-shared FNO may utilize the Fourier neural operator 300 depicted in FIG. 3 with the FNO applied on layout tokens instead of the entire layout image. Layout tokens are tiles of the overall high-definition image of the circuit layout. For example, the token-shared convolution operation may share each 3×3 convolution kernel across 3×3 tokens (tiles). A design layout image Zₜ∈R^{H×W} is partitioned into non-overlapped patches, referred as tokens:

$${Z}_{t} = [ \begin{matrix}{Z}_{t , 1 , 1} & {Z}_{t , 1 , 2} & … & {Z}_{t , 1 , n} \\ {Z}_{t , 2 , 1} & {Z}_{t , 2 , 2} & … & {Z}_{t , 2 , n} \\ … & … & … & … \\ {Z}_{t , m , 1} & {Z}_{t , m , 2} & … & {Z}_{t , m , n}\end{matrix} ] . \qquad Equation 5$$

where Z_{t, i, j}∈R^{k×k}'s are layout tokens, H=mk and W=nk. The shared FNO is represented by ƒ (·;W1) and the first-level token embedding is

T_{i,j}=ƒ(Z_{t,i,j};W₁),t=1,2, . . . ,m,j=1,2, . . . ,n, Equation 6

where W∈C^{k×k×d} and d denote the image depth. For example a color image of dimensions H×W×3 has a height of H pixels, a depth of W pixels, and a depth of d=3 color values (three channels). A gray scale image may comprise only one channel.

Equation (6) represents an algorithm that may be executed efficiently via batch processing, for example by applying the FNO on each token after collecting all tokens in a batch. A smaller k indicates a shared (among all tokens) FNO with fewer trainable parameters. This token-shared approach sacrifices some global information acquisition for model size.

To tackle this limitation, a second-level token embedding is introduced via a token-wise convolution with W2∈R^{(2s+1)×(2s+1)} (W2 being the kernel of the token-wise convolution, and comprising trainable parameters):

$${T}_{i , j} = {\sum }_{{t}_{x} = - s}^{s} {\sum }_{{t}_{y} = - s}^{s} {W}_{2} [ i + {t}_{x} , j + {t}_{y} ] \cdot {\tilde{T}}_{i + {t}_{x} , j + {t}_{y}} , \qquad Equation 7$$

which finally formulates the layout global embedding:

$$T = [ \begin{matrix}{T}_{1 , 1} & {T}_{1 , 2} & … & {T}_{1 , n} \\ {T}_{2 , 1} & {T}_{2 , 2} & … & {T}_{2 , n} \\ … & … & … & … \\ {T}_{m , 1} & {T}_{m , 2} & … & {T}_{m , n}\end{matrix} ] \qquad Equation 8$$

The first level embedding is obtained by applying a FNO on each token. The second level embedding is the output of token-wise convolution.

Equation (7) defines how tokens at different spatial locations are mixed (via the token-wise convolution) and hence addresses the token boundary inconsistency issue and long-range dependency requirements. Table 1 compares CFNO and FNO from the perspective of computing complexity and data flow, where N=HW=mnk² is the total size of Zₜ, d is the number of channels lifted in the FNO, k is the token size, and mn represents the total number of tokens in the design layout image. Typically s«k, where s is a number of frequency components in the FNO. This enables the CFNO to exhibit both computing and memory efficiency.

TABLE 1
Comparison between FNO and CFNO.

| Operator | FNO | CFNO |
|---|---|---|
| FLOPS | N logN + Nd² | N logk² + s²mnd² |
| Parameter | Nd² | s²d² |
| DataFlow | [symbol] -Linear- [symbol] ⁻¹ | [symbol] -Linear - [symbol] ⁻¹-Conv |

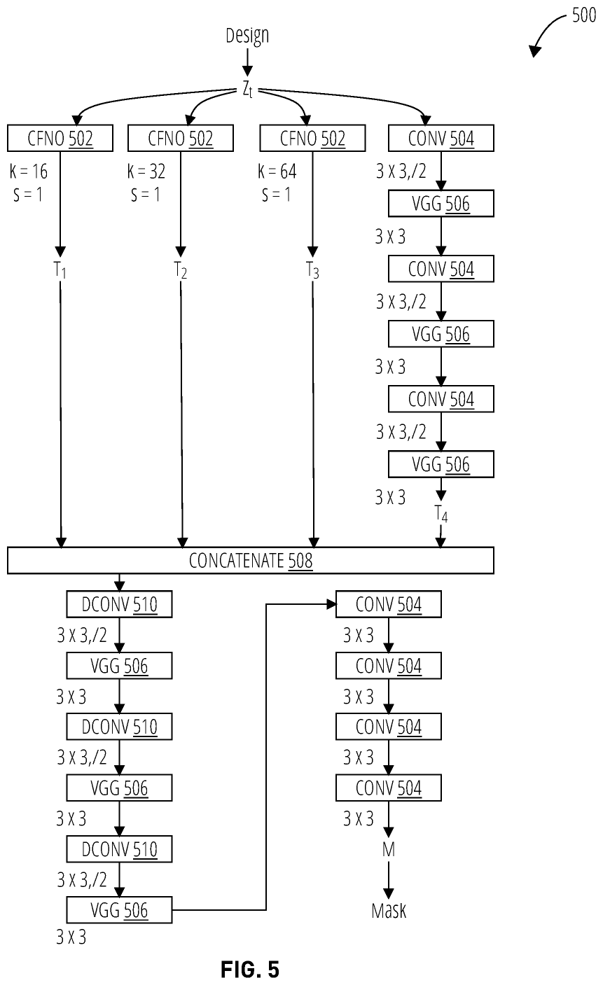

FIG. 5 depicts a CFNO-based mask optimizer network 500 in one embodiment. In FIG. 5, CONV and DCONV represent convolution layers 504 and transposed convolution layers 510. VGG denotes a VGG-net structure 506, which comprises stacked convolution blocks in manners known in the art; 3×3 indicates the convolution kernel size; /2 represents a stride of 2; and k, s define the layout token size and the token-wise convolution kernel size, respectively. The depicted VGG-net structure 506 is merely one specific example structure of a VGG-net that may be utilized.

The CFNO-based mask optimizer network 500 is characterized by two key hyper-parameters: the token size (k×k pixels) and the token-wise convolution kernel size 2(stride)+1 where stride is the stride size of the convolution. These two parameters work together to determine how global layout information is acquired. The network architecture in this example comprises four embedding paths.

Three paths are CFNO units 502 comprising different token sizes to enable multi-scale token embedding. The three paths each operate on the same input tensor. The fourth path comprises several groups of convolution layers 504, a particular CFNO embodiment characterized by k=1. This is one embodiment; other embodiments may comprise only two, or more than three FNO paths and different k characterization of the fourth path (e.g., k=4). Other embodiments may comprise more than one convolution path, for example three such paths each characterized with a different k value, such as k=1, k=2, and k=4.

Discrete Fourier Transform algorithms rely upon periodic image inputs to carry out the global convolution operation. This is not necessarily the case for layout images. The fourth convolution path therefore provides for compensation for boundary information.

Each shared FNO, by its structural nature, truncates high frequency coefficients to focus the CFNO-based mask optimizer network 500 on global information acquisition. These high frequency components are however important is mask learning, because pixel-level changes on masks will result in magnified changes to wafer images. The convolution path may therefore be designed to compensate for high frequency information loss. Once the token embedding from the four learning paths is established, an aggregation (e.g., concatenation operation 508) is performed to gather learned information. This is followed in the example embodiment by a series of convolution layers 504 and transposed convolution layers 510 to generate masks.

The machine learning models for mask optimization may be trained to perform discriminative tasks (classification, segmentation, object detection, and so on). The models may be trained perform these tasks to fit a group of observations treated as training samples X-Y, where X={x₁, x₂, . . . } is a feature vector input to a machine learning model with corresponding labels Y={y₁, y₂, . . . } identifying the training target. Typically a given xᵢ, yᵢ is unique. For example, in the well-known MNIST hand-written digits classification tasks, an image containing the digit “6” will have the label 6 and it cannot be something else. Under this scenario, a machine learning model ƒ(·;w) will have a very clear training objective, i.e.,

$${min}_{w} {\sum }_{i} l ( f ( {x}_{i} ; w ) , {y}_{i} ) ,$$

where l(·) is some designed cost function that determines the distance between ƒ(xᵢ;w) and yᵢ. During the inference phase on new observations, ƒ is acceptable if ∀xᵢ∈X_{new}, ƒ(xᵢ;w) is close to y₁.

However, there may be exceptions such as the well-known MLMO problem, where X represents the target layout design and Y represents the corresponding masks. Y may be obtained via some numerical mask optimizer running OPC or ILT. However, the input designs and masks are binary data. This makes the numerical optimization flow non-convex and hence only some local optimal solutions are obtained when solving Y to obtain the training set. During inference, it cannot be determined whether the model is performing accurately by measuring the distance between ƒ(xᵢ;w) and yᵢ and another tool, such as a lithography checker, may be needed to evaluate the mask quality.

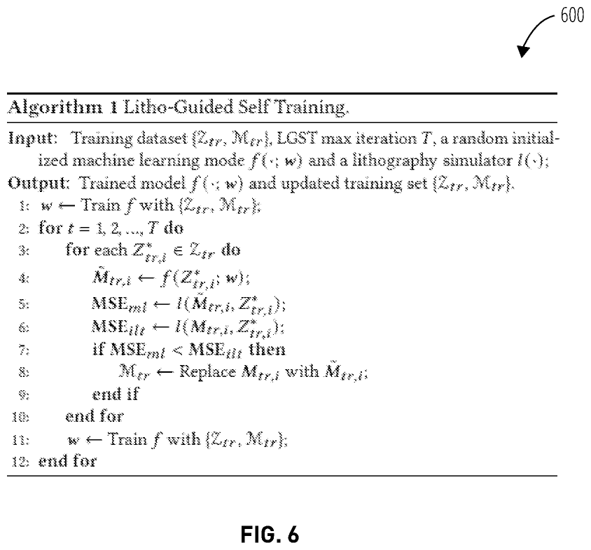

To address this problem, the machine learning model may learn from a training set that is not initially “golden”, e.g., with some inaccurate labels. FIG. 6 depicts an embodiment of an observation refinement algorithm 600 for this purpose. The observation refinement algorithm 600 is described in more detail below.

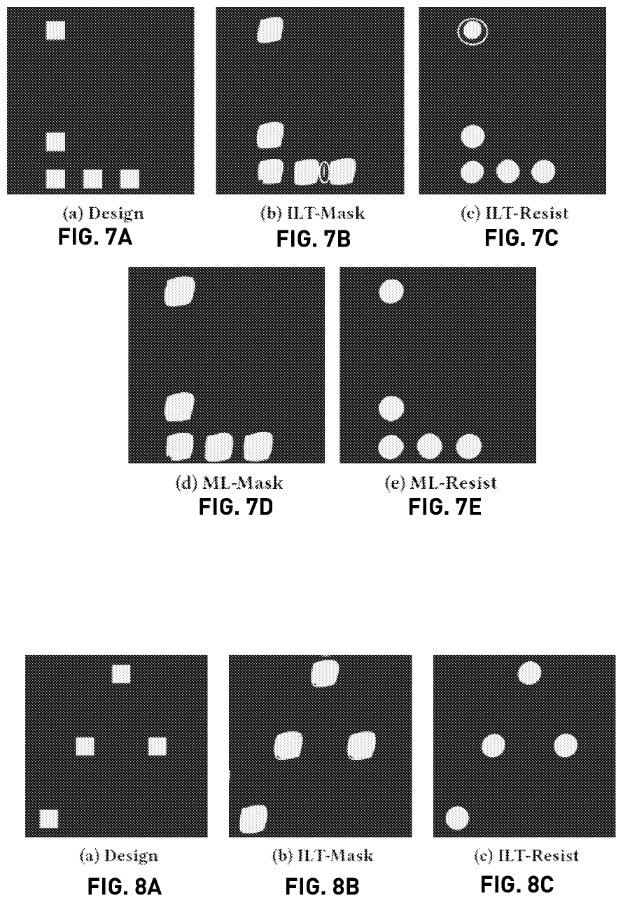

FIG. 7A depicts part of a circuit design comprising via arrays. FIG. 7B depicts a mask for this portion of the circuit, generated by a level-set ILT algorithm. FIG. 7C depicts a nominal resist image from the ILT-generated mask. FIG. 7D depicts a mask generated by the machine learning model, and FIG. 7E depicts a nominal resist image generated from the ML-generated mask.

Compared to the neural network generated mask (FIG. 7D), the ILT-generated mask (FIG. 7B) comprises rule-violation artifacts (circled in the figure). The isolated resist image is much smaller than the target and the shape in the ML-generated resist image (FIG. 7E). This is because the ILT is a gradient-based solution to minimize the pixelwise difference between the simulated contours and the design target. If shapes in a design are unevenly distributed, the low density regions will have smaller gradient and thus cannot be optimized efficiently. The machine learning model appears to classify the isolated mask shape in the training instance as “bad”, based on learning it derived from other training instances. Training instances that comprise evenly distributed, isolated shapes may be identified and removed or compensated for.

FIG. 8A-FIG. 8C shows how a level-set ILT tool can perform optimization on such training instances to integrate the lithography physics in the neural network design. This enables efficient learning of corner cases in the training set and therefore enables better mask quality.

The observation refinement algorithm 600 implements a training flow where the training set and the machine learning model may be updated alternatively, termed herein as “litho-guided self training (OR)”. The first step is to train the machine learning model with the initial training set (line 1), where masks are generated from the ILT engine. Following steps are performing a number T rounds of litho-guided self training (lines 2-12). In each OR round, model inference is carried out on the training set to obtain the model generated masks (line 4). Both the ML-generated mask and ILT-generated mask are input into a lithography simulation tool to measure the resist quality (lines 5-6). In this example MSE is used for a quality metric. If the machine learning generated mask has better resist quality than the ILT created mask, it is replaced in the training set (lines 7-9). At the end of T rounds of OR, the model is retrained with the most recent version of the training set.

The algorithms and techniques disclosed herein, including algorithms represented concisely as formulas or equations, and the neural network embodiments depicted and described herein, may be implemented by computing devices utilizing one or more graphic processing unit (GPU) and/or general purpose data processor (e.g., a ‘central processing unit or CPU) to execute instruction sets embodying the algorithms and networks. Exemplary architectures will now be described that may be configured to implement the techniques disclosed herein on such devices.

The following description may use certain acronyms and abbreviations as follows:
“DPC” refers to a “data processing cluster”;
“GPC” refers to a “general processing cluster”;
“I/O” refers to a “input/output”;
“L1 cache” refers to “level one cache”;
“L2 cache” refers to “level two cache”;
“LSU” refers to a “load/store unit”;
“MMU” refers to a “memory management unit”;
“MPC” refers to an “M-pipe controller”;
“PPU” refers to a “parallel processing unit”;
“PROP” refers to a “pre-raster operations unit”;
“ROP” refers to a “raster operations”;
“SFU” refers to a “special function unit”;
“SM” refers to a “streaming multiprocessor”;
“Viewport SCC” refers to “viewport scale, cull, and clip”;
“WDX” refers to a “work distribution crossbar”; and
“XBar” refers to a “crossbar”.

### Parallel Processing Unit

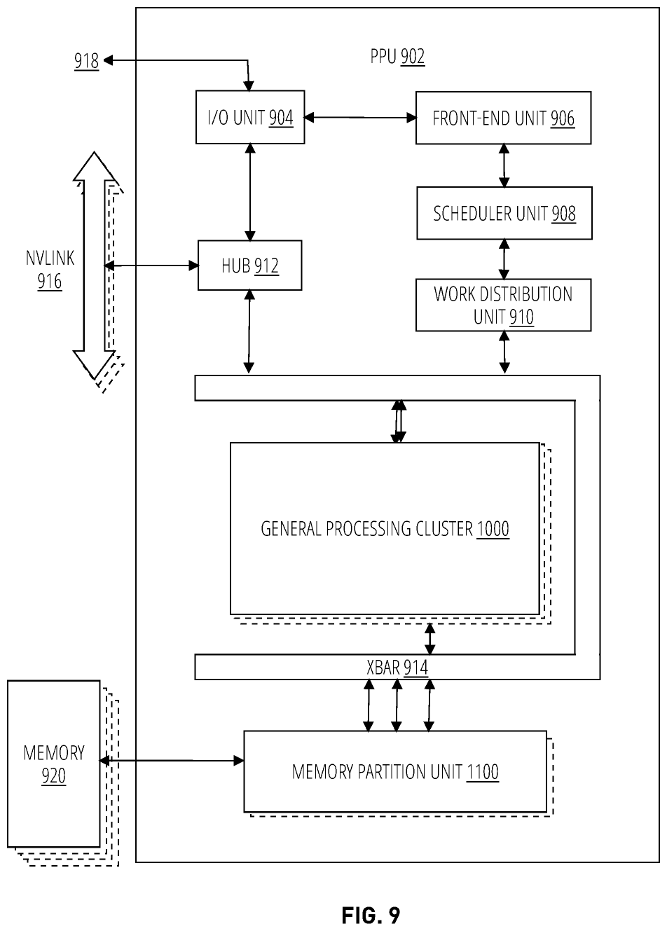

FIG. 9 depicts a parallel processing unit 902, in accordance with an embodiment. In an embodiment, the parallel processing unit 902 is a multi-threaded processor that is implemented on one or more integrated circuit devices. The parallel processing unit 902 is a latency hiding architecture designed to process many threads in parallel. A thread (e.g., a thread of execution) is an instantiation of a set of instructions configured to be executed by the parallel processing unit 902. In an embodiment, the parallel processing unit 902 is a graphics processing unit (GPU) configured to implement a graphics rendering pipeline for processing three-dimensional (3D) graphics data in order to generate two-dimensional (2D) image data for display on a display device such as a liquid crystal display (LCD) device. In other embodiments, the parallel processing unit 902 may be utilized for performing general-purpose computations. While one exemplary parallel processor is provided herein for illustrative purposes, it should be strongly noted that such processor is set forth for illustrative purposes only, and that any processor may be employed to supplement and/or substitute for the same.

One or more parallel processing unit 902 modules may be configured to accelerate thousands of High Performance Computing (HPC), data center, and machine learning applications. The parallel processing unit 902 may be configured to accelerate numerous deep learning systems and applications including autonomous vehicle platforms, deep learning, high-accuracy speech, image, and text recognition systems, intelligent video analytics, molecular simulations, drug discovery, disease diagnosis, weather forecasting, big data analytics, astronomy, molecular dynamics simulation, financial modeling, robotics, factory automation, real-time language translation, online search optimizations, and personalized user recommendations, and the like.

As shown in FIG. 9, the parallel processing unit 902 includes an I/O unit 904, a front-end unit 906, a scheduler unit 908, a work distribution unit 910, a hub 912, a crossbar 914, one or more general processing cluster 1000 modules, and one or more memory partition unit 1100 modules. The parallel processing unit 902 may be connected to a host processor or other parallel processing unit 902 modules via one or more high-speed NVLink 916 interconnects. The parallel processing unit 902 may be connected to a host processor or other peripheral devices via an interconnect 918. The parallel processing unit 902 may also be connected to a local memory comprising a number of memory 920 devices. In an embodiment, the local memory may comprise a number of dynamic random access memory (DRAM) devices. The DRAM devices may be configured as a high-bandwidth memory (HBM) subsystem, with multiple DRAM dies stacked within each device. The memory 920 may comprise logic to configure the parallel processing unit 902 to carry out aspects of the techniques disclosed herein.

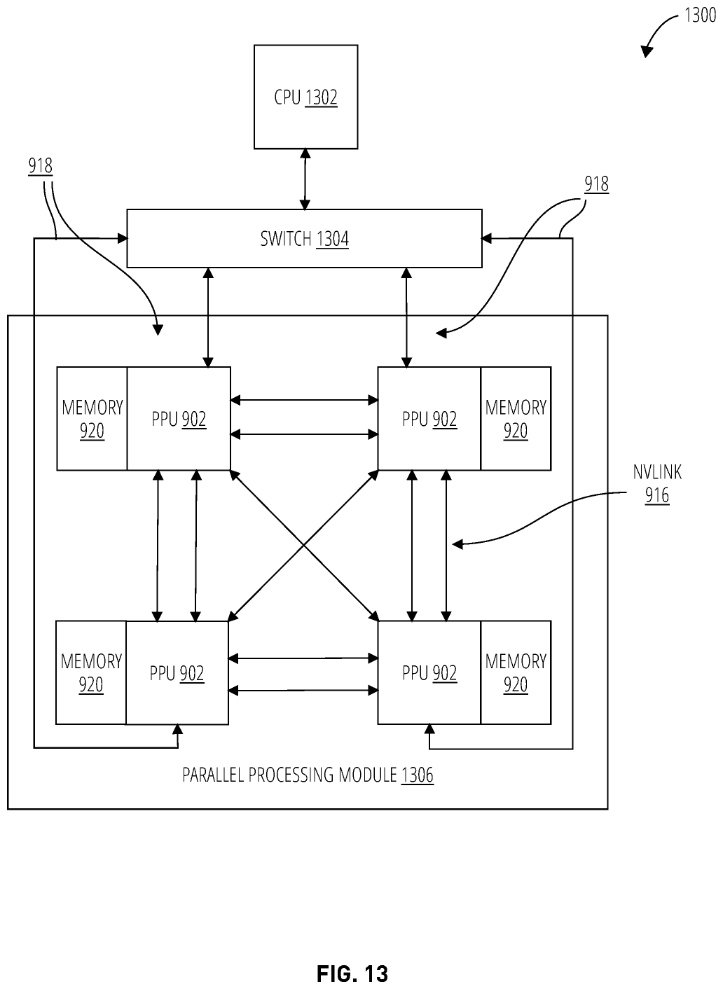

The NVLink 916 interconnect enables systems to scale and include one or more parallel processing unit 902 modules combined with one or more CPUs, supports cache coherence between the parallel processing unit 902 modules and CPUs, and CPU mastering. Data and/or commands may be transmitted by the NVLink 916 through the hub 912 to/from other units of the parallel processing unit 902 such as one or more copy engines, a video encoder, a video decoder, a power management unit, etc. (not explicitly shown). The NVLink 916 is described in more detail in conjunction with FIG. 13.

The I/O unit 904 is configured to transmit and receive communications (e.g., commands, data, etc.) from a host processor (not shown) over the interconnect 918. The I/O unit 904 may communicate with the host processor directly via the interconnect 918 or through one or more intermediate devices such as a memory bridge. In an embodiment, the I/O unit 904 may communicate with one or more other processors, such as one or more parallel processing unit 902 modules via the interconnect 918. In an embodiment, the I/O unit 904 implements a Peripheral Component Interconnect Express (PCIe) interface for communications over a PCIe bus and the interconnect 918 is a PCIe bus. In alternative embodiments, the I/O unit 904 may implement other types of well-known interfaces for communicating with external devices.

The I/O unit 904 decodes packets received via the interconnect 918. In an embodiment, the packets represent commands configured to cause the parallel processing unit 902 to perform various operations. The I/O unit 904 transmits the decoded commands to various other units of the parallel processing unit 902 as the commands may specify. For example, some commands may be transmitted to the front-end unit 906. Other commands may be transmitted to the hub 912 or other units of the parallel processing unit 902 such as one or more copy engines, a video encoder, a video decoder, a power management unit, etc. (not explicitly shown). In other words, the I/O unit 904 is configured to route communications between and among the various logical units of the parallel processing unit 902.

In an embodiment, a program executed by the host processor encodes a command stream in a buffer that provides workloads to the parallel processing unit 902 for processing. A workload may comprise several instructions and data to be processed by those instructions. The buffer is a region in a memory that is accessible (e.g., read/write) by both the host processor and the parallel processing unit 902. For example, the I/O unit 904 may be configured to access the buffer in a system memory connected to the interconnect 918 via memory requests transmitted over the interconnect 918. In an embodiment, the host processor writes the command stream to the buffer and then transmits a pointer to the start of the command stream to the parallel processing unit 902. The front-end unit 906 receives pointers to one or more command streams. The front-end unit 906 manages the one or more streams, reading commands from the streams and forwarding commands to the various units of the parallel processing unit 902.

The front-end unit 906 is coupled to a scheduler unit 908 that configures the various general processing cluster 1000 modules to process tasks defined by the one or more streams. The scheduler unit 908 is configured to track state information related to the various tasks managed by the scheduler unit 908. The state may indicate which general processing cluster 1000 a task is assigned to, whether the task is active or inactive, a priority level associated with the task, and so forth. The scheduler unit 908 manages the execution of a plurality of tasks on the one or more general processing cluster 1000 modules.

The scheduler unit 908 is coupled to a work distribution unit 910 that is configured to dispatch tasks for execution on the general processing cluster 1000 modules. The work distribution unit 910 may track a number of scheduled tasks received from the scheduler unit 908. In an embodiment, the work distribution unit 910 manages a pending task pool and an active task pool for each of the general processing cluster 1000 modules. The pending task pool may comprise a number of slots (e.g., 32 slots) that contain tasks assigned to be processed by a particular general processing cluster 1000. The active task pool may comprise a number of slots (e.g., 4 slots) for tasks that are actively being processed by the general processing cluster 1000 modules. As a general processing cluster 1000 finishes the execution of a task, that task is evicted from the active task pool for the general processing cluster 1000 and one of the other tasks from the pending task pool is selected and scheduled for execution on the general processing cluster 1000. If an active task has been idle on the general processing cluster 1000, such as while waiting for a data dependency to be resolved, then the active task may be evicted from the general processing cluster 1000 and returned to the pending task pool while another task in the pending task pool is selected and scheduled for execution on the general processing cluster 1000.

The work distribution unit 910 communicates with the one or more general processing cluster 1000 modules via crossbar 914. The crossbar 914 is an interconnect network that couples many of the units of the parallel processing unit 902 to other units of the parallel processing unit 902. For example, the crossbar 914 may be configured to couple the work distribution unit 910 to a particular general processing cluster 1000. Although not shown explicitly, one or more other units of the parallel processing unit 902 may also be connected to the crossbar 914 via the hub 912.

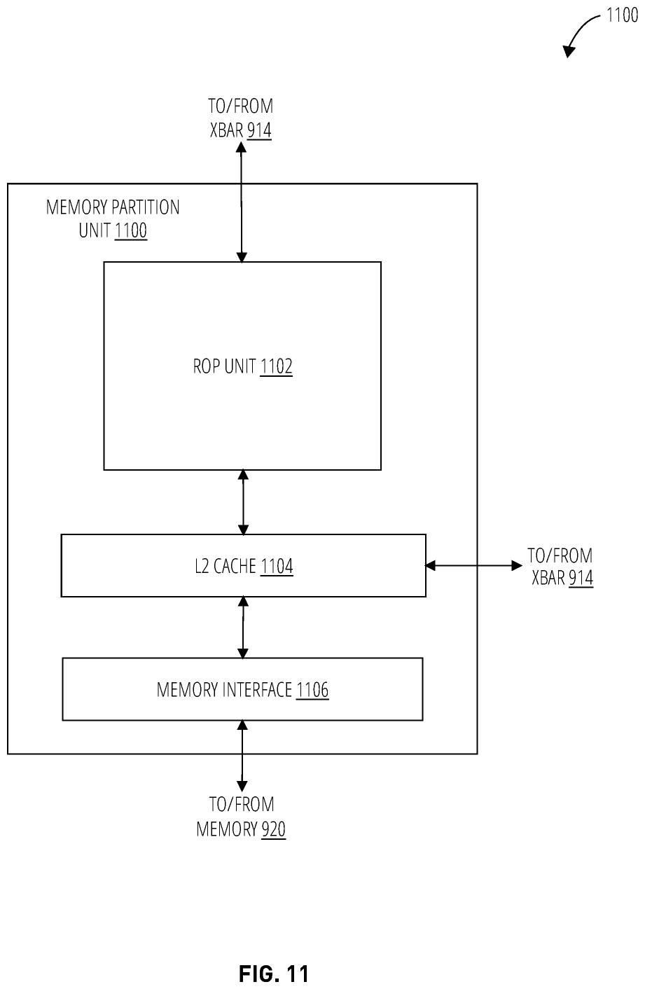

The tasks are managed by the scheduler unit 908 and dispatched to a general processing cluster 1000 by the work distribution unit 910. The general processing cluster 1000 is configured to process the task and generate results. The results may be consumed by other tasks within the general processing cluster 1000, routed to a different general processing cluster 1000 via the crossbar 914, or stored in the memory 920. The results can be written to the memory 920 via the memory partition unit 1100 modules, which implement a memory interface for reading and writing data to/from the memory 920. The results can be transmitted to another parallel processing unit 902 or CPU via the NVLink 916. In an embodiment, the parallel processing unit 902 includes a number U of memory partition unit 1100 modules that is equal to the number of separate and distinct memory 920 devices coupled to the parallel processing unit 902. A memory partition unit 1100 will be described in more detail below in conjunction with FIG. 11.

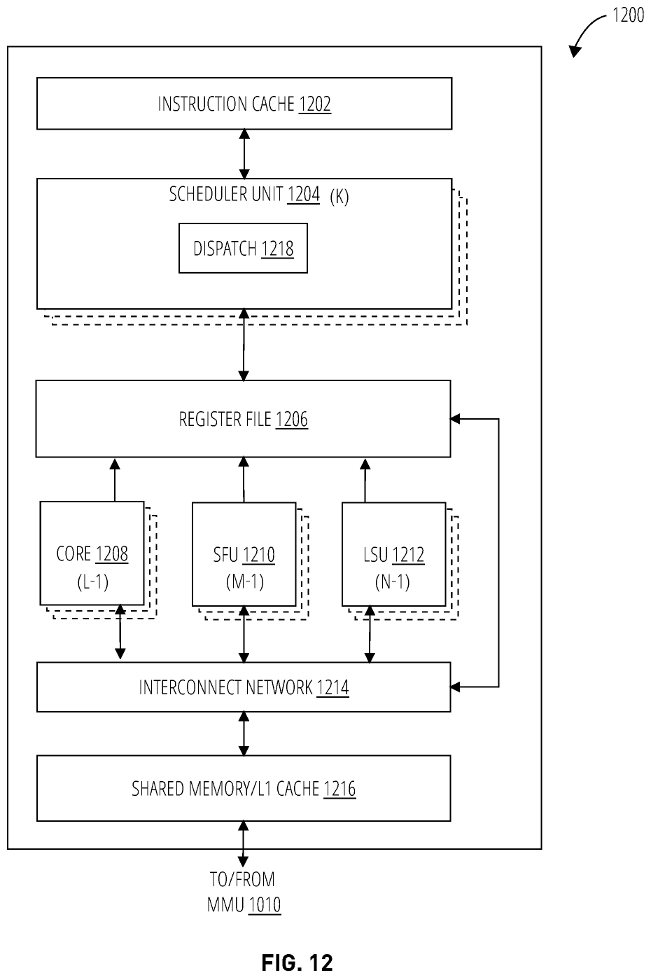

In an embodiment, a host processor executes a driver kernel that implements an application programming interface (API) that enables one or more applications executing on the host processor to schedule operations for execution on the parallel processing unit 902. In an embodiment, multiple compute applications are simultaneously executed by the parallel processing unit 902 and the parallel processing unit 902 provides isolation, quality of service (QoS), and independent address spaces for the multiple compute applications. An application may generate instructions (e.g., API calls) that cause the driver kernel to generate one or more tasks for execution by the parallel processing unit 902. The driver kernel outputs tasks to one or more streams being processed by the parallel processing unit 902. Each task may comprise one or more groups of related threads, referred to herein as a warp. In an embodiment, a warp comprises 32 related threads that may be executed in parallel. Cooperating threads may refer to a plurality of threads including instructions to perform the task and that may exchange data through shared memory. Threads and cooperating threads are described in more detail in conjunction with FIG. 12.

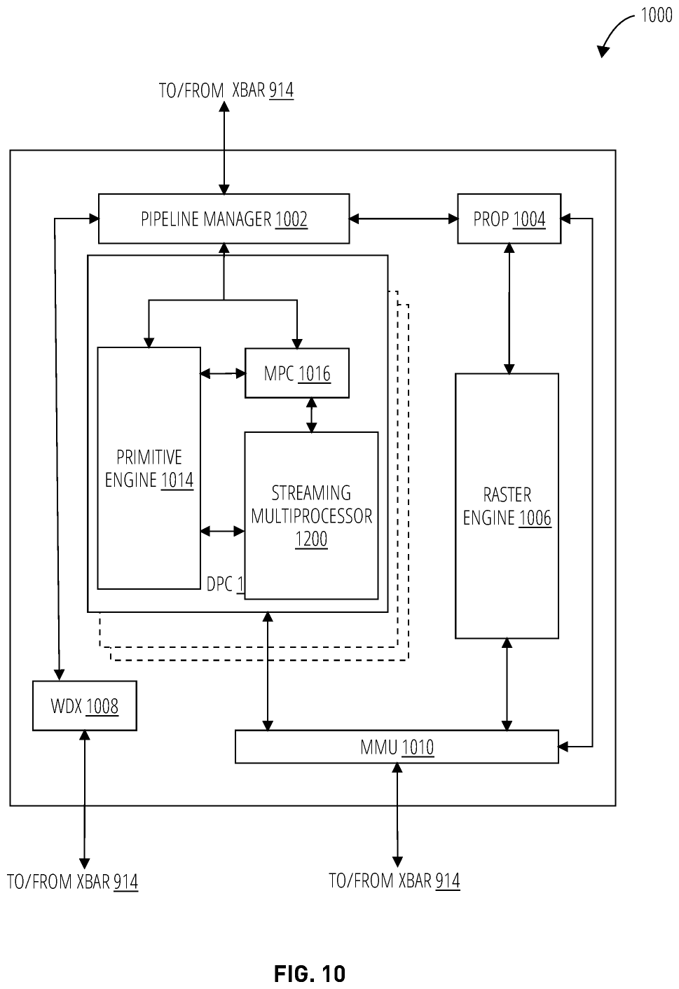

FIG. 10 depicts a general processing cluster 1000 of the parallel processing unit 902 of FIG. 9, in accordance with an embodiment. As shown in FIG. 10, each general processing cluster 1000 includes a number of hardware units for processing tasks. In an embodiment, each general processing cluster 1000 includes a pipeline manager 1002, a pre-raster operations unit 1004, a raster engine 1006, a work distribution crossbar 1008, a memory management unit 1010, and one or more data processing cluster 1012. It will be appreciated that the general processing cluster 1000 of FIG. 10 may include other hardware units in lieu of or in addition to the units shown in FIG. 10.

In an embodiment, the operation of the general processing cluster 1000 is controlled by the pipeline manager 1002. The pipeline manager 1002 manages the configuration of the one or more data processing cluster 1012 modules for processing tasks allocated to the general processing cluster 1000. In an embodiment, the pipeline manager 1002 may configure at least one of the one or more data processing cluster 1012 modules to implement at least a portion of a graphics rendering pipeline. For example, a data processing cluster 1012 may be configured to execute a vertex shader program on the programmable streaming multiprocessor 1200. The pipeline manager 1002 may also be configured to route packets received from the work distribution unit 910 to the appropriate logical units within the general processing cluster 1000. For example, some packets may be routed to fixed function hardware units in the pre-raster operations unit 1004 and/or raster engine 1006 while other packets may be routed to the data processing cluster 1012 modules for processing by the primitive engine 1014 or the streaming multiprocessor 1200. In an embodiment, the pipeline manager 1002 may configure at least one of the one or more data processing cluster 1012 modules to implement a neural network model and/or a computing pipeline.

The pre-raster operations unit 1004 is configured to route data generated by the raster engine 1006 and the data processing cluster 1012 modules to a Raster Operations (ROP) unit, described in more detail in conjunction with FIG. 11. The pre-raster operations unit 1004 may also be configured to perform optimizations for color blending, organize pixel data, perform address translations, and the like.

The raster engine 1006 includes a number of fixed function hardware units configured to perform various raster operations. In an embodiment, the raster engine 1006 includes a setup engine, a coarse raster engine, a culling engine, a clipping engine, a fine raster engine, and a tile coalescing engine. The setup engine receives transformed vertices and generates plane equations associated with the geometric primitive defined by the vertices. The plane equations are transmitted to the coarse raster engine to generate coverage information (e.g., an x, y coverage mask for a tile) for the primitive. The output of the coarse raster engine is transmitted to the culling engine where fragments associated with the primitive that fail a z-test are culled, and transmitted to a clipping engine where fragments lying outside a viewing frustum are clipped. Those fragments that survive clipping and culling may be passed to the fine raster engine to generate attributes for the pixel fragments based on the plane equations generated by the setup engine. The output of the raster engine 1006 comprises fragments to be processed, for example, by a fragment shader implemented within a data processing cluster 1012.

Each data processing cluster 1012 included in the general processing cluster 1000 includes an M-pipe controller 1016, a primitive engine 1014, and one or more streaming multiprocessor 1200 modules. The M-pipe controller 1016 controls the operation of the data processing cluster 1012, routing packets received from the pipeline manager 1002 to the appropriate units in the data processing cluster 1012. For example, packets associated with a vertex may be routed to the primitive engine 1014, which is configured to fetch vertex attributes associated with the vertex from the memory 920. In contrast, packets associated with a shader program may be transmitted to the streaming multiprocessor 1200.

The streaming multiprocessor 1200 comprises a programmable streaming processor that is configured to process tasks represented by a number of threads. Each streaming multiprocessor 1200 is multi-threaded and configured to execute a plurality of threads (e.g., 32 threads) from a particular group of threads concurrently. In an embodiment, the streaming multiprocessor 1200 implements a Single-Instruction, Multiple-Data (SIMD) architecture where each thread in a group of threads (e.g., a warp) is configured to process a different set of data based on the same set of instructions. All threads in the group of threads execute the same instructions. In another embodiment, the streaming multiprocessor 1200 implements a Single-Instruction, Multiple Thread (SIMT) architecture where each thread in a group of threads is configured to process a different set of data based on the same set of instructions, but where individual threads in the group of threads are allowed to diverge during execution. In an embodiment, a program counter, call stack, and execution state is maintained for each warp, enabling concurrency between warps and serial execution within warps when threads within the warp diverge. In another embodiment, a program counter, call stack, and execution state is maintained for each individual thread, enabling equal concurrency between all threads, within and between warps. When execution state is maintained for each individual thread, threads executing the same instructions may be converged and executed in parallel for maximum efficiency. The streaming multiprocessor 1200 will be described in more detail below in conjunction with FIG. 12.

The memory management unit 1010 provides an interface between the general processing cluster 1000 and the memory partition unit 1100. The memory management unit 1010 may provide translation of virtual addresses into physical addresses, memory protection, and arbitration of memory requests. In an embodiment, the memory management unit 1010 provides one or more translation lookaside buffers (TLBs) for performing translation of virtual addresses into physical addresses in the memory 920.

FIG. 11 depicts a memory partition unit 1100 of the parallel processing unit 902 of FIG. 9, in accordance with an embodiment. As shown in FIG. 11, the memory partition unit 1100 includes a raster operations unit 1102, a level two cache 1104, and a memory interface 1106. The memory interface 1106 is coupled to the memory 920. Memory interface 1106 may implement 32, 64, 128, 1024-bit data buses, or the like, for high-speed data transfer. In an embodiment, the parallel processing unit 902 incorporates U memory interface 1106 modules, one memory interface 1106 per pair of memory partition unit 1100 modules, where each pair of memory partition unit 1100 modules is connected to a corresponding memory 920 device. For example, parallel processing unit 902 may be connected to up to Y memory 920 devices, such as high bandwidth memory stacks or graphics double-data-rate, version 5, synchronous dynamic random access memory, or other types of persistent storage.

In an embodiment, the memory interface 1106 implements an HBM2 memory interface and Y equals half U. In an embodiment, the HBM2 memory stacks are located on the same physical package as the parallel processing unit 902, providing substantial power and area savings compared with conventional GDDR5 SDRAM systems. In an embodiment, each HBM2 stack includes four memory dies and Y equals 4, with HBM2 stack including two 128-bit channels per die for a total of 8 channels and a data bus width of 1024 bits.

In an embodiment, the memory 920 supports Single-Error Correcting Double-Error Detecting (SECDED) Error Correction Code (ECC) to protect data. ECC provides higher reliability for compute applications that are sensitive to data corruption. Reliability is especially important in large-scale cluster computing environments where parallel processing unit 902 modules process very large datasets and/or run applications for extended periods.

In an embodiment, the parallel processing unit 902 implements a multi-level memory hierarchy. In an embodiment, the memory partition unit 1100 supports a unified memory to provide a single unified virtual address space for CPU and parallel processing unit 902 memory, enabling data sharing between virtual memory systems. In an embodiment the frequency of accesses by a parallel processing unit 902 to memory located on other processors is traced to ensure that memory pages are moved to the physical memory of the parallel processing unit 902 that is accessing the pages more frequently. In an embodiment, the NVLink 916 supports address translation services allowing the parallel processing unit 902 to directly access a CPU's page tables and providing full access to CPU memory by the parallel processing unit 902.

In an embodiment, copy engines transfer data between multiple parallel processing unit 902 modules or between parallel processing unit 902 modules and CPUs. The copy engines can generate page faults for addresses that are not mapped into the page tables. The memory partition unit 1100 can then service the page faults, mapping the addresses into the page table, after which the copy engine can perform the transfer. In a conventional system, memory is pinned (e.g., non-pageable) for multiple copy engine operations between multiple processors, substantially reducing the available memory. With hardware page faulting, addresses can be passed to the copy engines without worrying if the memory pages are resident, and the copy process is transparent.

Data from the memory 920 or other system memory may be fetched by the memory partition unit 1100 and stored in the level two cache 1104, which is located on-chip and is shared between the various general processing cluster 1000 modules. As shown, each memory partition unit 1100 includes a portion of the level two cache 1104 associated with a corresponding memory 920 device. Lower level caches may then be implemented in various units within the general processing cluster 1000 modules. For example, each of the streaming multiprocessor 1200 modules may implement an L1 cache. The L1 cache is private memory that is dedicated to a particular streaming multiprocessor 1200. Data from the level two cache 1104 may be fetched and stored in each of the L1 caches for processing in the functional units of the streaming multiprocessor 1200 modules. The level two cache 1104 is coupled to the memory interface 1106 and the crossbar 914.

The raster operations unit 1102 performs graphics raster operations related to pixel color, such as color compression, pixel blending, and the like. The raster operations unit 1102 also implements depth testing in conjunction with the raster engine 1006, receiving a depth for a sample location associated with a pixel fragment from the culling engine of the raster engine 1006. The depth is tested against a corresponding depth in a depth buffer for a sample location associated with the fragment. If the fragment passes the depth test for the sample location, then the raster operations unit 1102 updates the depth buffer and transmits a result of the depth test to the raster engine 1006. It will be appreciated that the number of partition memory partition unit 1100 modules may be different than the number of general processing cluster 1000 modules and, therefore, each raster operations unit 1102 may be coupled to each of the general processing cluster 1000 modules. The raster operations unit 1102 tracks packets received from the different general processing cluster 1000 modules and determines which general processing cluster 1000 that a result generated by the raster operations unit 1102 is routed to through the crossbar 914. Although the raster operations unit 1102 is included within the memory partition unit 1100 in FIG. 11, in other embodiment, the raster operations unit 1102 may be outside of the memory partition unit 1100. For example, the raster operations unit 1102 may reside in the general processing cluster 1000 or another unit.

FIG. 12 illustrates the streaming multiprocessor 1200 of FIG. 10, in accordance with an embodiment. As shown in FIG. 12, the streaming multiprocessor 1200 includes an instruction cache 1202, one or more scheduler unit 1204 modules (e.g., such as scheduler unit 908), a register file 1206, one or more processing core 1208 modules, one or more special function unit 1210 modules, one or more load/store unit 1212 modules, an interconnect network 1214, and a shared memory/L1 cache 1216.

As described above, the work distribution unit 910 dispatches tasks for execution on the general processing cluster 1000 modules of the parallel processing unit 902. The tasks are allocated to a particular data processing cluster 1012 within a general processing cluster 1000 and, if the task is associated with a shader program, the task may be allocated to a streaming multiprocessor 1200. The scheduler unit 908 receives the tasks from the work distribution unit 910 and manages instruction scheduling for one or more thread blocks assigned to the streaming multiprocessor 1200. The scheduler unit 1204 schedules thread blocks for execution as warps of parallel threads, where each thread block is allocated at least one warp. In an embodiment, each warp executes 32 threads. The scheduler unit 1204 may manage a plurality of different thread blocks, allocating the warps to the different thread blocks and then dispatching instructions from the plurality of different cooperative groups to the various functional units (e.g., core 1208 modules, special function unit 1210 modules, and load/store unit 1212 modules) during each clock cycle.

Cooperative Groups is a programming model for organizing groups of communicating threads that allows developers to express the granularity at which threads are communicating, enabling the expression of richer, more efficient parallel decompositions. Cooperative launch APIs support synchronization amongst thread blocks for the execution of parallel algorithms. Conventional programming models provide a single, simple construct for synchronizing cooperating threads: a barrier across all threads of a thread block (e.g., the syncthreads( ) function). However, programmers would often like to define groups of threads at smaller than thread block granularities and synchronize within the defined groups to enable greater performance, design flexibility, and software reuse in the form of collective group-wide function interfaces.

Cooperative Groups enables programmers to define groups of threads explicitly at sub-block (e.g., as small as a single thread) and multi-block granularities, and to perform collective operations such as synchronization on the threads in a cooperative group. The programming model supports clean composition across software boundaries, so that libraries and utility functions can synchronize safely within their local context without having to make assumptions about convergence. Cooperative Groups primitives enable new patterns of cooperative parallelism, including producer-consumer parallelism, opportunistic parallelism, and global synchronization across an entire grid of thread blocks.

A dispatch 1218 unit is configured within the scheduler unit 1204 to transmit instructions to one or more of the functional units. In one embodiment, the scheduler unit 1204 includes two dispatch 1218 units that enable two different instructions from the same warp to be dispatched during each clock cycle. In alternative embodiments, each scheduler unit 1204 may include a single dispatch 1218 unit or additional dispatch 1218 units.

Each streaming multiprocessor 1200 includes a register file 1206 that provides a set of registers for the functional units of the streaming multiprocessor 1200. In an embodiment, the register file 1206 is divided between each of the functional units such that each functional unit is allocated a dedicated portion of the register file 1206. In another embodiment, the register file 1206 is divided between the different warps being executed by the streaming multiprocessor 1200. The register file 1206 provides temporary storage for operands connected to the data paths of the functional units.

Each streaming multiprocessor 1200 comprises L processing core 1208 modules. In an embodiment, the streaming multiprocessor 1200 includes a large number (e.g., 128, etc.) of distinct processing core 1208 modules. Each core 1208 may include a fully-pipelined, single-precision, double-precision, and/or mixed precision processing unit that includes a floating point arithmetic logic unit and an integer arithmetic logic unit. In an embodiment, the floating point arithmetic logic units implement the IEEE 754-2008 standard for floating point arithmetic. In an embodiment, the core 1208 modules include 64 single-precision (32-bit) floating point cores, 64 integer cores, 32 double-precision (64-bit) floating point cores, and 8 tensor cores.

Tensor cores configured to perform matrix operations, and, in an embodiment, one or more tensor cores are included in the core 1208 modules. In particular, the tensor cores are configured to perform deep learning matrix arithmetic, such as convolution operations for neural network training and inferencing. In an embodiment, each tensor core operates on a 4×4 matrix and performs a matrix multiply and accumulate operation D=A′B+C, where A, B, C, and D are 4×4 matrices.

In an embodiment, the matrix multiply inputs A and B are 16-bit floating point matrices, while the accumulation matrices C and D may be 16-bit floating point or 32-bit floating point matrices. Tensor Cores operate on 16-bit floating point input data with 32-bit floating point accumulation. The 16-bit floating point multiply requires 64 operations and results in a full precision product that is then accumulated using 32-bit floating point addition with the other intermediate products for a 4×4×4 matrix multiply. In practice, Tensor Cores are used to perform much larger two-dimensional or higher dimensional matrix operations, built up from these smaller elements. An API, such as CUDA 9 C++ API, exposes specialized matrix load, matrix multiply and accumulate, and matrix store operations to efficiently use Tensor Cores from a CUDA-C++ program. At the CUDA level, the warp-level interface assumes 16×16 size matrices spanning all 32 threads of the warp.

Each streaming multiprocessor 1200 also comprises M special function unit 1210 modules that perform special functions (e.g., attribute evaluation, reciprocal square root, and the like). In an embodiment, the special function unit 1210 modules may include a tree traversal unit configured to traverse a hierarchical tree data structure. In an embodiment, the special function unit 1210 modules may include texture unit configured to perform texture map filtering operations. In an embodiment, the texture units are configured to load texture maps (e.g., a 2D array of texels) from the memory 920 and sample the texture maps to produce sampled texture values for use in shader programs executed by the streaming multiprocessor 1200. In an embodiment, the texture maps are stored in the shared memory/L1 cache 1216. The texture units implement texture operations such as filtering operations using mip-maps (e.g., texture maps of varying levels of detail). In an embodiment, each streaming multiprocessor 1200 includes two texture units.

Each streaming multiprocessor 1200 also comprises N load/store unit 1212 modules that implement load and store operations between the shared memory/L1 cache 1216 and the register file 1206. Each streaming multiprocessor 1200 includes an interconnect network 1214 that connects each of the functional units to the register file 1206 and the load/store unit 1212 to the register file 1206 and shared memory/L1 cache 1216. In an embodiment, the interconnect network 1214 is a crossbar that can be configured to connect any of the functional units to any of the registers in the register file 1206 and connect the load/store unit 1212 modules to the register file 1206 and memory locations in shared memory/L1 cache 1216.

The shared memory/L1 cache 1216 is an array of on-chip memory that allows for data storage and communication between the streaming multiprocessor 1200 and the primitive engine 1014 and between threads in the streaming multiprocessor 1200. In an embodiment, the shared memory/L1 cache 1216 comprises 128 KB of storage capacity and is in the path from the streaming multiprocessor 1200 to the memory partition unit 1100. The shared memory/L1 cache 1216 can be used to cache reads and writes. One or more of the shared memory/L1 cache 1216, level two cache 1104, and memory 920are backing stores.

Combining data cache and shared memory functionality into a single memory block provides the best overall performance for both types of memory accesses. The capacity is usable as a cache by programs that do not use shared memory. For example, if shared memory is configured to use half of the capacity, texture and load/store operations can use the remaining capacity. Integration within the shared memory/L1 cache 1216 enables the shared memory/L1 cache 1216 to function as a high-throughput conduit for streaming data while simultaneously providing high-bandwidth and low-latency access to frequently reused data.

When configured for general purpose parallel computation, a simpler configuration can be used compared with graphics processing. Specifically, the fixed function graphics processing units shown in FIG. 9, are bypassed, creating a much simpler programming model. In the general purpose parallel computation configuration, the work distribution unit 910 assigns and distributes blocks of threads directly to the data processing cluster 1012 modules. The threads in a block execute the same program, using a unique thread ID in the calculation to ensure each thread generates unique results, using the streaming multiprocessor 1200 to execute the program and perform calculations, shared memory/L1 cache 1216 to communicate between threads, and the load/store unit 1212 to read and write global memory through the shared memory/L1 cache 1216 and the memory partition unit 1100. When configured for general purpose parallel computation, the streaming multiprocessor 1200 can also write commands that the scheduler unit 908 can use to launch new work on the data processing cluster 1012 modules.

The parallel processing unit 902 may be included in a desktop computer, a laptop computer, a tablet computer, servers, supercomputers, a smart-phone (e.g., a wireless, hand-held device), personal digital assistant (PDA), a digital camera, a vehicle, a head mounted display, a hand-held electronic device, and the like. In an embodiment, the parallel processing unit 902 is embodied on a single semiconductor substrate. In another embodiment, the parallel processing unit 902 is included in a system-on-a-chip (SoC) along with one or more other devices such as additional parallel processing unit 902 modules, the memory 920, a reduced instruction set computer (RISC) CPU, a memory management unit (MMU), a digital-to-analog converter (DAC), and the like.

In an embodiment, the parallel processing unit 902 may be included on a graphics card that includes one or more memory devices. The graphics card may be configured to interface with a PCIe slot on a motherboard of a desktop computer. In yet another embodiment, the parallel processing unit 902 may be an integrated graphics processing unit (iGPU) or parallel processor included in the chipset of the motherboard.

### Exemplary Computing System

Systems with multiple GPUs and CPUs are used in a variety of industries as developers expose and leverage more parallelism in applications such as artificial intelligence computing. High-performance GPU-accelerated systems with tens to many thousands of compute nodes are deployed in data centers, research facilities, and supercomputers to solve ever larger problems. As the number of processing devices within the high-performance systems increases, the communication and data transfer mechanisms need to scale to support the increased bandwidth.

FIG. 13 is a conceptual diagram of a processing system 1300 implemented using the parallel processing unit 902 of FIG. 9, in accordance with an embodiment. The processing system 1300 includes a central processing unit 1302, switch 1304, and multiple parallel processing unit 902 modules each and respective memory 920 modules. The NVLink 916 provides high-speed communication links between each of the parallel processing unit 902 modules. Although a particular number of NVLink 916 and interconnect 918 connections are illustrated in FIG. 13, the number of connections to each parallel processing unit 902 and the central processing unit 1302 may vary. The switch 1304 interfaces between the interconnect 918 and the central processing unit 1302. The parallel processing unit 902 modules, memory 920 modules, and NVLink 916 connections may be situated on a single semiconductor platform to form a parallel processing module 1306. In an embodiment, the switch 1304 supports two or more protocols to interface between various different connections and/or links.

In another embodiment (not shown), the NVLink 916 provides one or more high-speed communication links between each of the parallel processing unit modules (parallel processing unit 902, parallel processing unit 902, parallel processing unit 902, and parallel processing unit 902) and the central processing unit 1302 and the switch 1304 interfaces between the interconnect 918 and each of the parallel processing unit modules. The parallel processing unit modules, memory 920 modules, and interconnect 918 may be situated on a single semiconductor platform to form a parallel processing module 1306. In yet another embodiment (not shown), the interconnect 918 provides one or more communication links between each of the parallel processing unit modules and the central processing unit 1302 and the switch 1304 interfaces between each of the parallel processing unit modules using the NVLink 916 to provide one or more high-speed communication links between the parallel processing unit modules. In another embodiment (not shown), the NVLink 916 provides one or more high-speed communication links between the parallel processing unit modules and the central processing unit 1302 through the switch 1304. In yet another embodiment (not shown), the interconnect 918 provides one or more communication links between each of the parallel processing unit modules directly. One or more of the NVLink 916 high-speed communication links may be implemented as a physical NVLink interconnect or either an on-chip or on-die interconnect using the same protocol as the NVLink 916.

In the context of the present description, a single semiconductor platform may refer to a sole unitary semiconductor-based integrated circuit fabricated on a die or chip. It should be noted that the term single semiconductor platform may also refer to multi-chip modules with increased connectivity which simulate on-chip operation and make substantial improvements over utilizing a conventional bus implementation. Of course, the various circuits or devices may also be situated separately or in various combinations of semiconductor platforms per the desires of the user. Alternately, the parallel processing module 1306 may be implemented as a circuit board substrate and each of the parallel processing unit modules and/or memory 920 modules may be packaged devices. In an embodiment, the central processing unit 1302, switch 1304, and the parallel processing module 1306 are situated on a single semiconductor platform.

In an embodiment, the signaling rate of each NVLink 916 is 20 to 25 Gigabits/second and each parallel processing unit module includes six NVLink 916 interfaces (as shown in FIG. 13, five NVLink 916 interfaces are included for each parallel processing unit module). Each NVLink 916 provides a data transfer rate of 25 Gigabytes/second in each direction, with six links providing 300 Gigabytes/second. The NVLink 916 can be used exclusively for PPU-to-PPU communication as shown in FIG. 13, or some combination of PPU-to-PPU and PPU-to-CPU, when the central processing unit 1302 also includes one or more NVLink 916 interfaces.

In an embodiment, the NVLink 916 allows direct load/store/atomic access from the central processing unit 1302 to each parallel processing unit module's memory 920. In an embodiment, the NVLink 916 supports coherency operations, allowing data read from the memory 920 modules to be stored in the cache hierarchy of the central processing unit 1302, reducing cache access latency for the central processing unit 1302. In an embodiment, the NVLink 916 includes support for Address Translation Services (ATS), enabling the parallel processing unit module to directly access page tables within the central processing unit 1302. One or more of the NVLink 916 may also be configured to operate in a low-power mode.

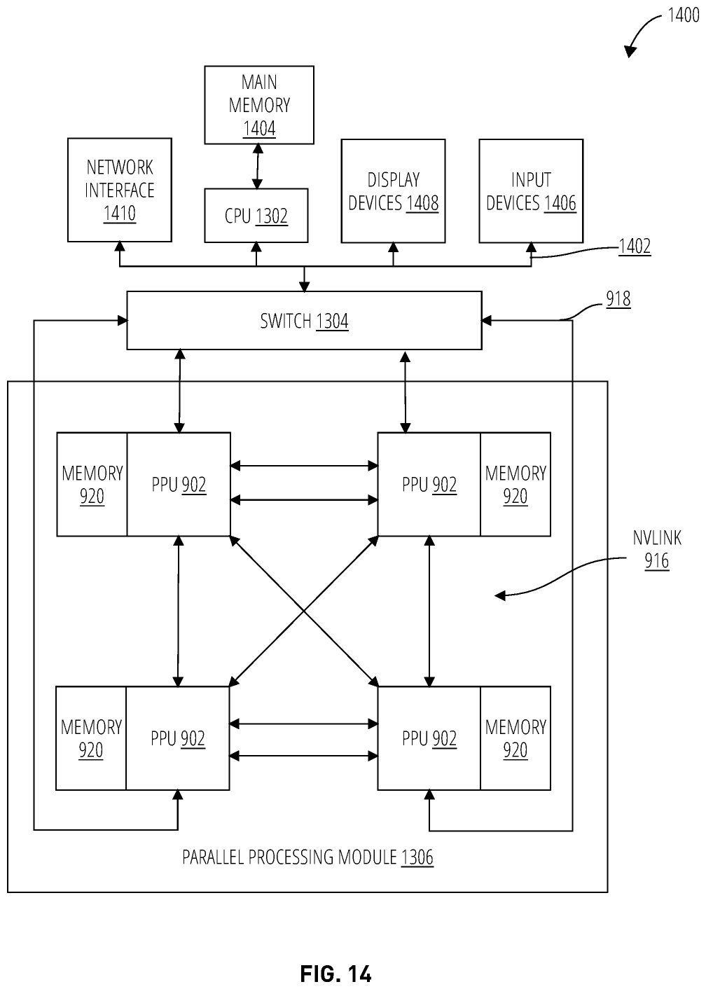

FIG. 14 depicts an exemplary processing system 1400 in which the various architecture and/or functionality of the various previous embodiments may be implemented. As shown, an exemplary processing system 1400 is provided including at least one central processing unit 1302 that is connected to a communications bus 1402. The communication communications bus 1402 may be implemented using any suitable protocol, such as PCI (Peripheral Component Interconnect), PCI-Express, AGP (Accelerated Graphics Port), HyperTransport, or any other bus or point-to-point communication protocol(s). The exemplary processing system 1400 also includes a main memory 1404. Control logic (software) and data are stored in the main memory 1404 which may take the form of random access memory (RAM).

The exemplary processing system 1400 also includes input devices 1406, the parallel processing module 1306, and display devices 1408, e.g. a conventional CRT (cathode ray tube), LCD (liquid crystal display), LED (light emitting diode), plasma display or the like. User input may be received from the input devices 1406, e.g., keyboard, mouse, touchpad, microphone, and the like. Each of the foregoing modules and/or devices may even be situated on a single semiconductor platform to form the exemplary processing system 1400. Alternately, the various modules may also be situated separately or in various combinations of semiconductor platforms per the desires of the user.

Further, the exemplary processing system 1400 may be coupled to a network (e.g., a telecommunications network, local area network (LAN), wireless network, wide area network (WAN) such as the Internet, peer-to-peer network, cable network, or the like) through a network interface 1410 for communication purposes.

The exemplary processing system 1400 may also include a secondary storage (not shown). The secondary storage includes, for example, a hard disk drive and/or a removable storage drive, representing a floppy disk drive, a magnetic tape drive, a compact disk drive, digital versatile disk (DVD) drive, recording device, universal serial bus (USB) flash memory. The removable storage drive reads from and/or writes to a removable storage unit in a well-known manner.

Computer programs, or computer control logic algorithms, may be stored in the main memory 1404 and/or the secondary storage. Such computer programs, when executed, enable the exemplary processing system 1400 to perform various functions. The main memory 1404, the storage, and/or any other storage are possible examples of computer-readable media.

The architecture and/or functionality of the various previous figures may be implemented in the context of a general computer system, a circuit board system, a game console system dedicated for entertainment purposes, an application-specific system, and/or any other desired system. For example, the exemplary processing system 1400 may take the form of a desktop computer, a laptop computer, a tablet computer, servers, supercomputers, a smart-phone (e.g., a wireless, hand-held device), personal digital assistant (PDA), a digital camera, a vehicle, a head mounted display, a hand-held electronic device, a mobile phone device, a television, workstation, game consoles, embedded system, and/or any other type of logic.

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

### Graphics Processing Pipeline

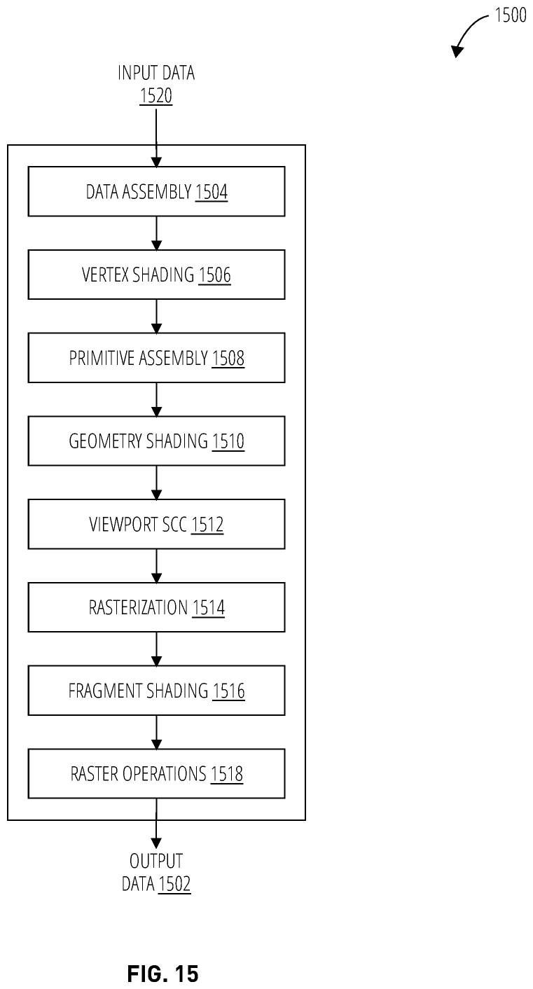

FIG. 15 is a conceptual diagram of a graphics processing pipeline 1500 implemented by the parallel processing unit 902 of FIG. 9, in accordance with an embodiment. In an embodiment, the parallel processing unit 902 comprises a graphics processing unit (GPU). The parallel processing unit 902 is configured to receive commands that specify shader programs for processing graphics data. Graphics data may be defined as a set of primitives such as points, lines, triangles, quads, triangle strips, and the like. Typically, a primitive includes data that specifies a number of vertices for the primitive (e.g., in a model-space coordinate system) as well as attributes associated with each vertex of the primitive. The parallel processing unit 902 can be configured to process the graphics primitives to generate a frame buffer (e.g., pixel data for each of the pixels of the display).

An application writes model data for a scene (e.g., a collection of vertices and attributes) to a memory such as a system memory or memory 920. The model data defines each of the objects that may be visible on a display. The application then makes an API call to the driver kernel that requests the model data to be rendered and displayed. The driver kernel reads the model data and writes commands to the one or more streams to perform operations to process the model data. The commands may reference different shader programs to be implemented on the streaming multiprocessor 1200 modules of the parallel processing unit 902 including one or more of a vertex shader, hull shader, domain shader, geometry shader, and a pixel shader. For example, one or more of the streaming multiprocessor 1200 modules may be configured to execute a vertex shader program that processes a number of vertices defined by the model data. In an embodiment, the different streaming multiprocessor 1200 modules may be configured to execute different shader programs concurrently. For example, a first subset of streaming multiprocessor 1200 modules may be configured to execute a vertex shader program while a second subset of streaming multiprocessor 1200 modules may be configured to execute a pixel shader program. The first subset of streaming multiprocessor 1200 modules processes vertex data to produce processed vertex data and writes the processed vertex data to the level two cache 1104 and/or the memory 920. After the processed vertex data is rasterized (e.g., transformed from three-dimensional data into two-dimensional data in screen space) to produce fragment data, the second subset of streaming multiprocessor 1200 modules executes a pixel shader to produce processed fragment data, which is then blended with other processed fragment data and written to the frame buffer in memory 920. The vertex shader program and pixel shader program may execute concurrently, processing different data from the same scene in a pipelined fashion until all of the model data for the scene has been rendered to the frame buffer. Then, the contents of the frame buffer are transmitted to a display controller for display on a display device.

The graphics processing pipeline 1500 is an abstract flow diagram of the processing steps implemented to generate 2D computer-generated images from 3D geometry data. As is well-known, pipeline architectures may perform long latency operations more efficiently by splitting up the operation into a plurality of stages, where the output of each stage is coupled to the input of the next successive stage. Thus, the graphics processing pipeline 1500 receives input data 601 that is transmitted from one stage to the next stage of the graphics processing pipeline 1500 to generate output data 1502. In an embodiment, the graphics processing pipeline 1500 may represent a graphics processing pipeline defined by the OpenGL® API. As an option, the graphics processing pipeline 1500 may be implemented in the context of the functionality and architecture of the previous Figures and/or any subsequent Figure(s).

As shown in FIG. 15, the graphics processing pipeline 1500 comprises a pipeline architecture that includes a number of stages. The stages include, but are not limited to, a data assembly 1504 stage, a vertex shading 1506 stage, a primitive assembly 1508 stage, a geometry shading 1510 stage, a viewport SCC 1512 stage, a rasterization 1514 stage, a fragment shading 1516 stage, and a raster operations 1518 stage. In an embodiment, the input data 1520 comprises commands that configure the processing units to implement the stages of the graphics processing pipeline 1500 and geometric primitives (e.g., points, lines, triangles, quads, triangle strips or fans, etc.) to be processed by the stages. The output data 1502 may comprise pixel data (e.g., color data) that is copied into a frame buffer or other type of surface data structure in a memory.

The data assembly 1504 stage receives the input data 1520 that specifies vertex data for high-order surfaces, primitives, or the like. The data assembly 1504 stage collects the vertex data in a temporary storage or queue, such as by receiving a command from the host processor that includes a pointer to a buffer in memory and reading the vertex data from the buffer. The vertex data is then transmitted to the vertex shading 1506 stage for processing.

The vertex shading 1506 stage processes vertex data by performing a set of operations (e.g., a vertex shader or a program) once for each of the vertices. Vertices may be, e.g., specified as a 4-coordinate vector (e.g., <x, y, z, w>) associated with one or more vertex attributes (e.g., color, texture coordinates, surface normal, etc.). The vertex shading 1506 stage may manipulate individual vertex attributes such as position, color, texture coordinates, and the like. In other words, the vertex shading 1506 stage performs operations on the vertex coordinates or other vertex attributes associated with a vertex. Such operations commonly including lighting operations (e.g., modifying color attributes for a vertex) and transformation operations (e.g., modifying the coordinate space for a vertex). For example, vertices may be specified using coordinates in an object-coordinate space, which are transformed by multiplying the coordinates by a matrix that translates the coordinates from the object-coordinate space into a world space or a normalized-device-coordinate (NCD) space. The vertex shading 1506 stage generates transformed vertex data that is transmitted to the primitive assembly 1508 stage.

The primitive assembly 1508 stage collects vertices output by the vertex shading 1506 stage and groups the vertices into geometric primitives for processing by the geometry shading 1510 stage. For example, the primitive assembly 1508 stage may be configured to group every three consecutive vertices as a geometric primitive (e.g., a triangle) for transmission to the geometry shading 1510 stage. In some embodiments, specific vertices may be reused for consecutive geometric primitives (e.g., two consecutive triangles in a triangle strip may share two vertices). The primitive assembly 1508 stage transmits geometric primitives (e.g., a collection of associated vertices) to the geometry shading 1510 stage.

The geometry shading 1510 stage processes geometric primitives by performing a set of operations (e.g., a geometry shader or program) on the geometric primitives. Tessellation operations may generate one or more geometric primitives from each geometric primitive. In other words, the geometry shading 1510 stage may subdivide each geometric primitive into a finer mesh of two or more geometric primitives for processing by the rest of the graphics processing pipeline 1500. The geometry shading 1510 stage transmits geometric primitives to the viewport SCC 1512 stage.

In an embodiment, the graphics processing pipeline 1500 may operate within a streaming multiprocessor and the vertex shading 1506 stage, the primitive assembly 1508 stage, the geometry shading 1510 stage, the fragment shading 1516 stage, and/or hardware/software associated therewith, may sequentially perform processing operations. Once the sequential processing operations are complete, in an embodiment, the viewport SCC 1512 stage may utilize the data. In an embodiment, primitive data processed by one or more of the stages in the graphics processing pipeline 1500 may be written to a cache (e.g. L1 cache, a vertex cache, etc.). In this case, in an embodiment, the viewport SCC 1512 stage may access the data in the cache. In an embodiment, the viewport SCC 1512 stage and the rasterization 1514 stage are implemented as fixed function circuitry.

The viewport SCC 1512 stage performs viewport scaling, culling, and clipping of the geometric primitives. Each surface being rendered to is associated with an abstract camera position. The camera position represents a location of a viewer looking at the scene and defines a viewing frustum that encloses the objects of the scene. The viewing frustum may include a viewing plane, a rear plane, and four clipping planes. Any geometric primitive entirely outside of the viewing frustum may be culled (e.g., discarded) because the geometric primitive will not contribute to the final rendered scene. Any geometric primitive that is partially inside the viewing frustum and partially outside the viewing frustum may be clipped (e.g., transformed into a new geometric primitive that is enclosed within the viewing frustum. Furthermore, geometric primitives may each be scaled based on a depth of the viewing frustum. All potentially visible geometric primitives are then transmitted to the rasterization 1514 stage.

The rasterization 1514 stage converts the 3D geometric primitives into 2D fragments (e.g. capable of being utilized for display, etc.). The rasterization 1514 stage may be configured to utilize the vertices of the geometric primitives to setup a set of plane equations from which various attributes can be interpolated. The rasterization 1514 stage may also compute a coverage mask for a plurality of pixels that indicates whether one or more sample locations for the pixel intercept the geometric primitive. In an embodiment, z-testing may also be performed to determine if the geometric primitive is occluded by other geometric primitives that have already been rasterized. The rasterization 1514 stage generates fragment data (e.g., interpolated vertex attributes associated with a particular sample location for each covered pixel) that are transmitted to the fragment shading 1516 stage.

The fragment shading 1516 stage processes fragment data by performing a set of operations (e.g., a fragment shader or a program) on each of the fragments. The fragment shading 1516 stage may generate pixel data (e.g., color values) for the fragment such as by performing lighting operations or sampling texture maps using interpolated texture coordinates for the fragment. The fragment shading 1516 stage generates pixel data that is transmitted to the raster operations 1518 stage.

The raster operations 1518 stage may perform various operations on the pixel data such as performing alpha tests, stencil tests, and blending the pixel data with other pixel data corresponding to other fragments associated with the pixel. When the raster operations 1518 stage has finished processing the pixel data (e.g., the output data 1502), the pixel data may be written to a render target such as a frame buffer, a color buffer, or the like.

It will be appreciated that one or more additional stages may be included in the graphics processing pipeline 1500 in addition to or in lieu of one or more of the stages described above. Various implementations of the abstract graphics processing pipeline may implement different stages. Furthermore, one or more of the stages described above may be excluded from the graphics processing pipeline in some embodiments (such as the geometry shading 1510 stage). Other types of graphics processing pipelines are contemplated as being within the scope of the present disclosure. Furthermore, any of the stages of the graphics processing pipeline 1500 may be implemented by one or more dedicated hardware units within a graphics processor such as parallel processing unit 902. Other stages of the graphics processing pipeline 1500 may be implemented by programmable hardware units such as the streaming multiprocessor 1200 of the parallel processing unit 902.

The graphics processing pipeline 1500 may be implemented via an application executed by a host processor, such as a CPU. In an embodiment, a device driver may implement an application programming interface (API) that defines various functions that can be utilized by an application in order to generate graphical data for display. The device driver is a software program that includes a plurality of instructions that control the operation of the parallel processing unit 902. The API provides an abstraction for a programmer that lets a programmer utilize specialized graphics hardware, such as the parallel processing unit 902, to generate the graphical data without requiring the programmer to utilize the specific instruction set for the parallel processing unit 902. The application may include an API call that is routed to the device driver for the parallel processing unit 902. The device driver interprets the API call and performs various operations to respond to the API call. In some instances, the device driver may perform operations by executing instructions on the CPU. In other instances, the device driver may perform operations, at least in part, by launching operations on the parallel processing unit 902 utilizing an input/output interface between the CPU and the parallel processing unit 902. In an embodiment, the device driver is configured to implement the graphics processing pipeline 1500 utilizing the hardware of the parallel processing unit 902.

Various programs may be executed within the parallel processing unit 902 in order to implement the various stages of the graphics processing pipeline 1500. For example, the device driver may launch a kernel on the parallel processing unit 902 to perform the vertex shading 1506 stage on one streaming multiprocessor 1200 (or multiple streaming multiprocessor 1200 modules). The device driver (or the initial kernel executed by the parallel processing unit 902) may also launch other kernels on the parallel processing unit 902 to perform other stages of the graphics processing pipeline 1500, such as the geometry shading 1510 stage and the fragment shading 1516 stage. In addition, some of the stages of the graphics processing pipeline 1500 may be implemented on fixed unit hardware such as a rasterizer or a data assembler implemented within the parallel processing unit 902. It will be appreciated that results from one kernel may be processed by one or more intervening fixed function hardware units before being processed by a subsequent kernel on a streaming multiprocessor 1200.

### LISTING OF DRAWING ELEMENTS

200 mask quality measurement
300 Fourier neural operator
400 convolutional Fourier neural operator
500 CFNO-based mask optimizer network
502 CFNO unit
504 convolution layer
506 VGG-net structure
508 concatenation operation
510 transposed convolution layer
600 observation refinement algorithm
902 parallel processing unit
904 I/O unit
906 front-end unit
908 scheduler unit
910 work distribution unit
912 hub
914 crossbar
916 NVLink
918 interconnect
920 memory
1000 general processing cluster
1002 pipeline manager
1004 pre-raster operations unit
1006 raster engine
1008 work distribution crossbar
1010 memory management unit
1012 data processing cluster
1014 primitive engine
1016 M-pipe controller
1100 memory partition unit
1102 raster operations unit
1104 level two cache
1106 memory interface
1200 streaming multiprocessor
1202 instruction cache
1204 scheduler unit
1206 register file
1208 core
1210 special function unit
1212 load/store unit
1214 interconnect network
1216 shared memory/L1 cache
1218 dispatch
1300 processing system
1302 central processing unit
1304 switch
1306 parallel processing module
1400 exemplary processing system
1402 communications bus
1404 main memory
1406 input devices
1408 display devices
1410 network interface
1500 graphics processing pipeline
1502 output data
1504 data assembly
1506 vertex shading
1508 primitive assembly
1510 geometry shading
1512 viewport SCC
1514 rasterization
1516 fragment shading
1518 raster operations
1520 input data

Various functional operations described herein may be implemented in logic that is referred to using a noun or noun phrase reflecting said operation or function. For example, an association operation may be carried out by an “associator” or “correlator”. Likewise, switching may be carried out by a “switch”, selection by a “selector”, and so on. “Logic” refers to machine memory circuits and non-transitory machine readable media comprising machine-executable instructions (software and firmware), and/or circuitry (hardware) which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory (both volatile and nonvolatile), and firmware are examples of logic. Logic specifically excludes pure signals or software per se (however does not exclude machine memories comprising software and thereby forming configurations of matter).

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical, such as an electronic circuit). More specifically, this formulation is used to indicate that this structure is arranged to perform the one or more tasks during operation. A structure can be said to be “configured to” perform some task even if the structure is not currently being operated. A “credit distribution circuit configured to distribute credits to a plurality of processor cores” is intended to cover, for example, an integrated circuit that has circuitry that performs this function during operation, even if the integrated circuit in question is not currently being used (e.g., a power supply is not connected to it). Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed FPGA, for example, would not be considered to be “configured to” perform some specific function, although it may be “configurable to” perform that function after programming.

Reciting in the appended claims that a structure is “configured to” perform one or more tasks is expressly intended not to invoke 35 U.S.C. § 112(f) for that claim element. Accordingly, claims in this application that do not otherwise include the “means for” [performing a function] construct should not be interpreted under 35 U.S.C § 112(f).

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

As used herein, the phrase “in response to” describes one or more factors that trigger an effect. This phrase does not foreclose the possibility that additional factors may affect or otherwise trigger the effect. That is, an effect may be solely in response to those factors, or may be in response to the specified factors as well as other, unspecified factors. Consider the phrase “perform A in response to B.” This phrase specifies that B is a factor that triggers the performance of A. This phrase does not foreclose that performing A may also be in response to some other factor, such as C. This phrase is also intended to cover an embodiment in which A is performed solely in response to B.

As used herein, the terms “first,” “second,” etc. are used as labels for nouns that they precede, and do not imply any type of ordering (e.g., spatial, temporal, logical, etc.), unless stated otherwise. For example, in a register file having eight registers, the terms “first register” and “second register” can be used to refer to any two of the eight registers, and not, for example, just logical registers 0 and 1.

When used in the claims, the term “or” is used as an inclusive or and not as an exclusive or. For example, the phrase “at least one of x, y, or z” means any one of x, y, and z, as well as any combination thereof.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

The subject matter of the present disclosure is described with specificity herein to meet statutory requirements. However, the description itself is not intended to limit the scope of this disclosure. Rather, the inventors have contemplated that the claimed subject matter might also be embodied in other ways, to include different steps or combinations of steps similar to the ones described in this document, in conjunction with other present or future technologies. Moreover, although the terms “step” and/or “block” may be used herein to connote different elements of methods employed, the terms should not be interpreted as implying any particular order among or between various steps herein disclosed unless and except when the order of individual steps is explicitly described.

Having thus described illustrative embodiments in detail, it will be apparent that modifications and variations are possible without departing from the scope of the invention as claimed. The scope of inventive subject matter is not limited to the depicted embodiments but is rather set forth in the following Claims.

What is claimed is:

1. A neural network comprising:
a token-shared Fourier neural operator unit;
a token-wise convolution layer; and
wherein the token-wise convolutional layer implements local-global mixing for circuit mask optimization.

2. The neural network of claim 1, the token-wise convolutional layer comprising a kernel size 2s+1, where s is a stride size of the convolution.

3. The neural network of claim 2, comprising a plurality of embedding paths.

4. The neural network of claim 3, wherein the embedding paths are configured with a variety of different token sizes.

5. The neural network of claim 3, wherein a number of the embedding paths is four.

6. The neural network of claim 5, wherein three of the four embedding paths comprise token sizes different from one another.

7. The neural network of claim 1, wherein one of the embedding paths comprises a token size of one to compensate for boundary conditions in the circuit mask.

8. The neural network of claim 1, further comprising a concatenator disposed to receive outputs of the embedding paths.

9. A circuit mask generator comprising:
a token-shared Fourier neural operator (FNO) unit comprising a plurality of distinct embedding paths;
the embedding paths configured to each input a same tensor representing features of a circuit mask and to apply a plurality of different token sizes to an embedding of the circuit mask;
a token-wise convolution layer; and
wherein the token-wise convolutional layer implements local-global mixing of the features of the circuit mask.

10. The circuit mask generator of claim 9, the token-wise convolution layer comprising a kernel size 2s+1, where s is a convolution stride size.

11. The circuit mask generator of claim 9, wherein the FNO unit comprises four embedding paths.

12. The circuit mask generator of claim 11, wherein three of the four embedding paths comprise token sizes different from one another.

13. The circuit mask generator of claim 9, wherein one of the embedding paths comprises a token size of one.

14. The circuit mask generator of claim 9, further comprising logic disposed to receive and concatenate outputs of the embedding paths.

15. A process for improving a circuit mask, the process comprising:
applying features of the circuit mask to a token-shared Fourier neural operator (FNO) unit comprising a plurality of distinct embedding paths;
wherein the embedding paths process the features with different token sizes to generate different embeddings of the circuit mask in a neural network; and
performing a token-wise convolutional to implement local-global mixing of the features of the circuit mask.

16. The process of claim 15, where the token-wise convolution operates with a kernel size 2s+1, where s is a convolution stride size.

17. The process of claim 15, wherein the FNO unit comprises four embedding paths.

18. The process of claim 17, wherein at least three of the four embedding paths comprise token sizes different from one another.

19. The process of claim 15, wherein one of the embedding paths comprises a token size of one.

20. The process of claim 15, further comprising:
concatenating outputs of the embedding paths.
